(19) United States
(12) Patent Application Publication
(10) Pub. No.: US 2014/0287588 A1
(43) Pub. Date: Sep. 25, 2014

(54) Deposition Method and Deposition Apparatus

(71) Applicant: ULVAC, INC., Chigasaki-shi, Kanagawa (JP)

(72) Inventor: Seiichi Takahashi, Shizuoka (JP)

(21) Appl. No.: 14/347,537

(22) PCT Filed: Apr. 26, 2013
(86) PCT No.: PCT/JP2013/002842

§ 371 Date: Jun. 10, 2014

(30) Foreign Application Priority Data
May 16, 2012 (JP) 2012-112085

(51) Int. Cl. H01L 21/02; H01L 21/67

(52) U.S. Cl. CPC H01L 21/02518; H01L 21/67207
USPC 438/694; 118/719

(57) ABSTRACT

[Object] To provide a deposition method and a deposition apparatus, which are capable of cleaning a surface of a silicon substrate and causing a single crystal film having excellent crystallinity to grow on the surface.

[Solving Means] A deposition method according to an embodiment of the present invention includes a process of etching a natural oxide film formed on a surface of a silicon substrate. The surface of the silicon substrate is cleaned. A film is caused to grow on the cleaned surface of the silicon substrate, the film including at least one of silicon and germanium.

### TECHNICAL FIELD

The present invention relates to a deposition method and a deposition apparatus, which cause a film to grow on a silicon substrate by a vapor-phase epitaxial growth method or the like.

### BACKGROUND ART

In a semiconductor element such as a DRAM (Dynamic Random Access Memory) and a flash memory, a plurality of thin-film transistors are formed. Such a transistor typically has a configuration in which a source and a drain, which are formed of silicon (Si), germanium (Ge), or a compound thereof, are formed on a surface of a silicon substrate on which impurity ions are diffused. The source and the drain can be formed by causing a single crystal film to grow on the surface of the silicon substrate by a vapor-phase epitaxial growth method.

In the vapor-phase epitaxial growth method, it is possible to obtain a single crystal film because crystals are arranged on the underlying silicon crystal surface if the surface of the silicon substrate is clean. On the other hand, it is very difficult to maintain the surface of the active silicon substrate in a clean state. For example, if the silicon substrate is exposed in the atmosphere, a natural oxide film is formed on the surface thereof immediately. In the case where the surface of the silicon substrate is not clean as described above, the crystal orientation of the film is not aligned in a direction and thus, it has been impossible to form a desired single crystal film.

In view of the above, Patent Document 1 describes a method in which a natural oxide film is converted into a volatile material at a temperature of about room temperature, the volatile material is decomposed by being heated to not more than 100° C., and the natural oxide film is removed by etching. According to the method, it is possible to etch the natural oxide film at low temperature while preventing the impurity ion doped on the silicon substrate from diffusing.

### CITATION LIST

### Patent Document

Patent Document 1: International Publication No. 2008/044577

### DISCLOSURE OF THE INVENTION

### Problem to be Solved by the Invention

On the other hand, even in a deposition apparatus maintained in a vacuum atmosphere, a single carbon (C) or fluorine (F) atom or a compound including these atoms attaches to the apparatus or floats in space. Moreover, the surface of the silicon substrate right after the etching process of the natural oxide film is in a very active state. Therefore, for example, even in the case where an etching process is performed on the natural oxide film, the surface of the silicon substrate may be polluted with these materials during or after the transportation to the deposition chamber and a desired film quality cannot be obtained in some cases.

In view of the circumstances as described above, it is an object of the present invention to provide a deposition method and a deposition apparatus, which are capable of cleaning a surface of a silicon substrate and causing a single crystal film having excellent crystallinity to grow on the surface.

### Means for Solving the Problem

In order to achieve the above-mentioned object, a deposition method according to an embodiment of the present invention includes a process of etching a natural oxide film formed on a surface of a silicon substrate.

The surface of the silicon substrate is cleaned.

A film is caused to grow on the cleaned surface of the silicon substrate, the film including at least one of silicon and germanium.

In order to achieve the above-mentioned object, a deposition apparatus according to an embodiment of the present invention includes an etching chamber, a deposition chamber, and a transporting mechanism.

The etching chamber includes a first supplying mechanism that supplies a first reaction gas for etching a natural oxide film formed on a surface of a silicon substrate.

The deposition chamber includes a second supplying mechanism that supplies a second reaction gas for cleaning the surface of the silicon substrate, a third supplying mechanism that supplies a raw material gas including at least one of silicon and germanium to the surface of the silicon substrate, and a heating mechanism that heats the silicon substrate.

The transporting mechanism is capable of transporting the silicon substrate from the etching chamber to the deposition chamber under vacuum.

### BRIEF DESCRIPTION OF DRAWINGS

FIG. 1 is a schematic configuration diagram showing a deposition apparatus according to a first embodiment of the present invention.

FIG. 2 is a schematic configuration diagram showing a main portion of the deposition apparatus according to the first embodiment of the present invention.

FIG. 3 is a flowchart for explaining a deposition method according to the first embodiment of the present invention.

FIG. 4A is a schematic diagram showing a form of a silicon substrate in a process of transporting the silicon substrate to an etching chamber in the deposition method according to the first embodiment of the present invention.

FIG. 4B is a schematic diagram showing a form of the silicon substrate after a natural oxide film is converted into a volatile material in an etching process in the deposition method according to the first embodiment of the present invention.

FIG. 4C is a schematic diagram showing a form of the silicon substrate after the etching process in the deposition method according to the first method of the present invention.

FIG. 4D is a schematic diagram showing a form of the silicon substrate after a vacuum transporting process in the deposition method according to the first method of the present invention.

FIG. 4E is a schematic diagram showing a form of the silicon substrate after a cleaning process in the deposition method according to the first method of the present invention.

FIG. 4F is a schematic diagram showing a form of the silicon substrate after a deposition process in the deposition method according to the first method of the present invention.

FIG. 5 is a schematic configuration diagram showing a main portion of a deposition apparatus according to a second embodiment of the present invention.

FIG. 6 is a flowchart for explaining a deposition method according to a third embodiment of the present invention.

### MODE(S) FOR CARRYING OUT THE INVENTION

A deposition method according to an embodiment of the present invention includes a process of etching a natural oxide film formed on a surface of a silicon substrate.

The surface of the silicon substrate is cleaned.

A film is caused to grow on the cleaned surface of the silicon substrate, the film including at least one of silicon and germanium.

With the method, it is possible to remove the natural oxide film formed on the surface of the silicon substrate by etching and to clean the surface more. Therefore, it is possible to clean the surface of the silicon substrate more reliably and to cause a single crystal film having excellent crystallinity to grow on the surface.

The deposition method may further include a process of transporting the silicon substrate from the etching chamber to a deposition chamber under vacuum.

Moreover, the natural oxide film may be etched in the etching chamber and the film may be caused to grow in the deposition chamber.

Accordingly, it is possible to transport the silicon substrate from the etching chamber to the deposition chamber without exposing it in the atmosphere, and to prevent the natural oxide film from reattaching to the surface of the silicon substrate. Therefore, it is possible to clean the surface of the substrate in the cleaning process more efficiently and reliably.

The surface of the silicon substrate may be cleaned in the deposition chamber.

Accordingly, it is possible to clean the surface after transporting the silicon substrate to the deposition chamber. Therefore, it is possible to clean also the material reacted with the surface of the substrate during or after the transportation to the deposition chamber and to cause the film to grow on the clean surface of the silicon substrate.

The surface of the silicon substrate may be cleaned by using a gas including a hydrogen radical.

Accordingly, in the case where a floating material such as single C, F, and O atoms and a compound thereof reacts with the surface of the silicon substrate and thus a reactant is generated, it is possible to remove these materials from the surface of the substrate by reducing the reactant by a hydrogen radical, for example. Moreover, because the hydrogen radical is active and has a reduction power greater than a normal hydrogen (hydrogen ion, hydrogen molecule), it is possible to perform the reaction at a temperature lower than the normal hydrogen.

Alternatively, the surface of the silicon substrate may be cleaned using a deposition gas.

Accordingly, the same gas can be used in the cleaning process and the process of causing a film to grow, and contamination does not occur due to the gas used to clean the growing film. Moreover, it is possible to shorten the time period for shifting from the cleaning process to the process of causing a film to grow because the processes can be performed continuously without changing the atmosphere.

Moreover, in the case where a silane-based gas is used to cause a film including silicon to grow on the surface of the silicon substrate, the silane-based gas may be used to clean the surface of the silicon substrate.

Because the silane-based gas can be used to deposit the film including silicon, it is possible to cause a film including silicon to appropriately grow on the surface of the silicon substrate without managing the time condition of the cleaning process strictly.

The silane-based gas having a first flow rate may be used when a film including silicon is caused to grow on the surface of the silicon substrate, and the silane-based gas having a second flow rate that is less than the first flow rate may be used when the surface of the silicon substrate is cleaned.

Accordingly, it is possible to reduce the material or the like attached to the surface of the substrate and to clean the surface without causing a film including silicon to grow on the surface of the silicon substrate in the cleaning process.

Moreover, in the case where a germane-based gas is used to cause a film including germanium to grow on the surface of the silicon substrate, the germane-based gas may be used to clean the surface of the silicon substrate.

The germane-based gas can be used to deposit a film including germanium. Accordingly, it is possible to cause a film including germanium to appropriately grow on the surface of the silicon substrate without managing the time condition of the cleaning process strictly.

In the processes of cleaning a surface of a silicon substrate and causing a film to grow, the silicon substrate may be heated to not more than 800° C.

With the temperature, it is possible to prevent the diffusion profile of impurity ions doped in the silicon substrate from changing.

In the process of etching a natural oxide film, the natural oxide film may be converted into volatile ammonium fluorosilicate by causing the natural oxide film to react with an ammonium fluoride gas.

Accordingly, it is possible to remove the natural oxide film by volatilizing the ammonium fluorosilicate.

Moreover, surfaces of a plurality of silicon substrates may be cleaned at the same time, and films may be caused to grow on the plurality of silicon substrates at the same time.

Accordingly, a so-called batch process can be performed, and it is possible to improve the productivity.

A deposition apparatus according to an embodiment of the present invention includes an etching chamber, a deposition chamber, and a transporting mechanism.

The etching chamber includes a first supplying mechanism that supplies a first reaction gas for etching a natural oxide film formed on a surface of a silicon substrate.

The deposition chamber includes a second supplying mechanism that supplies a second reaction gas for cleaning the surface of the silicon substrate, a third supplying mechanism that supplies a raw material gas including at least one of silicon and germanium to the surface of the silicon substrate, and a heating mechanism that heats the silicon substrate.

The transporting mechanism is capable of transporting the silicon substrate from the etching chamber to the deposition chamber under vacuum.

With the configuration, it is possible to transport the silicon substrate by the transporting mechanism under vacuum and to clean the surface of the substrate and cause a film to grow on the surface of the substrate in the deposition chamber after the natural oxide film is etched in the etching chamber. Therefore, it is possible to remove the natural oxide film on the surface of the silicon substrate in the etching chamber, and to clean the surface before a film is caused to grow in the deposition chamber. Therefore, it is possible to clean the surface of the substrate more reliably. Moreover, because the substrate can be transported between the etching chamber and the deposition chamber under vacuum, it is possible to prevent the natural oxide film from reattaching to the surface and to perform the cleaning process more efficiently.

The second supplying mechanism may include a first supplying unit that is capable of supplying a hydrogen radical.

Accordingly, it is possible to use the hydrogen radical to clean the surface. Because the hydrogen radical has a reduction power greater than a normal hydrogen, it is possible to clean the surface at a temperature lower than the normal hydrogen.

Alternatively, the second supplying mechanism may include a second supplying unit that is capable of supplying a silane-based gas.

Accordingly, it is possible to use the silane-based gas to clean the surface. Because the silnae-based gas can be used to deposit the film including silicon, it is possible to cause a film including silicon to appropriately grow on the surface of the silicon substrate without managing the time condition of the cleaning process strictly.

The first supplying mechanism may include a third supplying unit that is capable of supplying a nitrogen fluoride gas and a fourth supplying unit that is capable of supplying a hydrogen radical.

Accordingly, it is possible to convert the natural oxide film into volatile ammonium fluorosilicate by causing the natural oxide film to react with an ammonium fluoride gas. Furthermore, it is possible to remove the natural oxide film by volatilizing the ammonium fluorosilicate.

The heating mechanism may be configured to heat inside of the deposition chamber to not more than 800° C.

With the temperature, it is possible to prevent the diffusion profile of impurity ions doped in the silicon substrate from collapsing.

The etching chamber and the deposition chamber may include respective substrate holders configured to be capable of holding a plurality of silicon substrates.

Accordingly, it is possible to clean surfaces of a plurality of silicon substrates at the same time, and to cause films to grow on the plurality of silicon substrates at the same time. Specifically, the batch process can be performed, and it is possible to improve the productivity.

Hereinafter, embodiments according to the present invention will be described with reference to the drawings.

### First Embodiment

### Deposition Apparatus

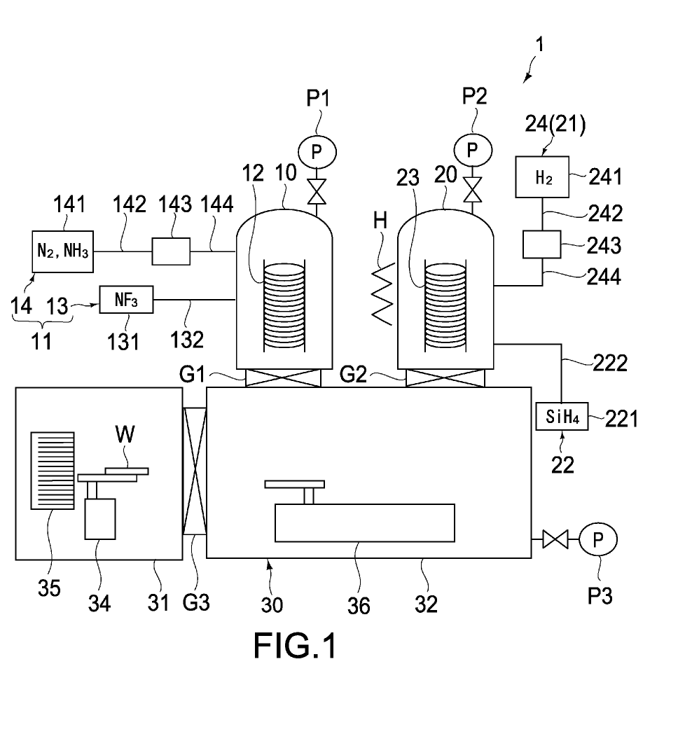

FIG. 1 is a schematic configuration diagram showing a deposition apparatus according to an embodiment of the present invention. A deposition apparatus 1 includes an etching chamber 10, a deposition chamber 20, and a transporting mechanism 30. In this embodiment, the deposition apparatus 1 is configured as an epitaxial vapor phase growing apparatus using a batch process system.

In this embodiment, the deposition apparatus 1 is an apparatus that causes a film to grow on a surface of a substrate (silicon substrate) W by a vapor-phase epitaxial growth method. The substrate W is a silicon wafer having a predetermined area on which impurity ions such as phosphorous (P) and boron (B) are doped, and is formed to have a diameter of about 300 mm. In this embodiment, the deposition apparatus 1 is used to cause a film including at least one of silicon and germanium to grow on the surface of the substrate W. The film is used as a source and a drain of a thin-film transistor, for example.

As shown in FIG. 1, the etching chamber 10 and the deposition chamber 20 are connected to each other via a transporting chamber 32 of the transporting mechanism 30. The substrate W is transported to the deposition chamber 20 after the natural oxide film is etched in the etching chamber 10. Furthermore, the surface of the substrate W is cleaned in the deposition chamber 20, and a silicon single crystal film is deposited on the surface by a vapor-phase epitaxial growth method.

Hereinafter, the configuration of respective units will be described.

### (Etching Chamber)

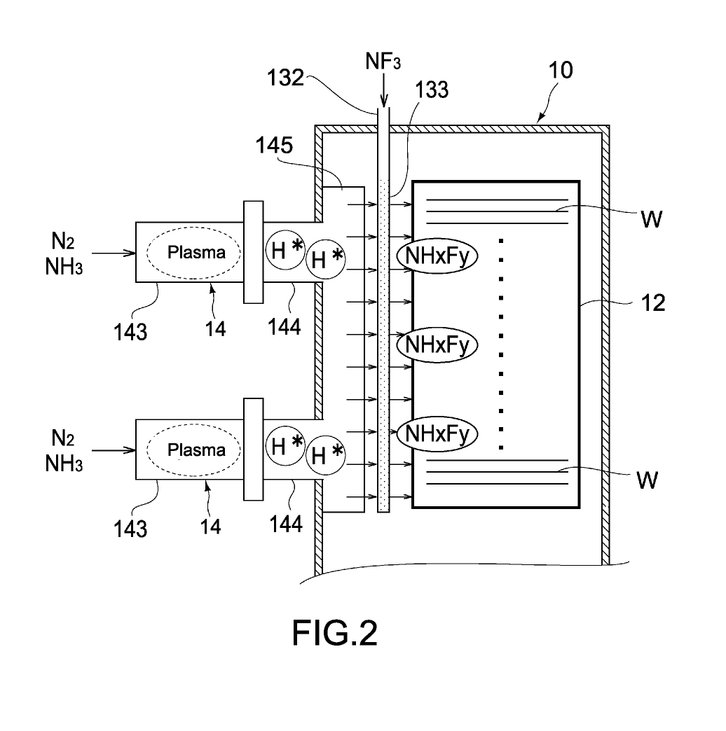

FIG. 2 is a schematic configuration diagram showing a main portion of the etching chamber 10. The etching chamber 10 includes a reactive gas supplying mechanism (first supplying mechanism) 11 that supplies a first reactive gas and a wafer boat (substrate holder) 12. The etching chamber 10 holds the substrate W by the wafer boat 12, and etches a natural oxidized film formed on the surface of the substrate W by the first reactive gas.

The etching chamber 10 is configured as a vertical etching apparatus, for example. Specifically, the etching chamber 10 has a cylindrical shape as a whole, and the axial direction (hereinafter, referred to as height direction of the etching chamber 10) is arranged substantially in parallel with the vertical direction. Moreover, the etching chamber 10 is connected to the transporting chamber 32 via a gate valve G1.

The etching chamber 10 is connected to an evacuation pump P1 formed of a dry pump or a turbo molecular pump, and is configured so that the inside thereof can be vacuum-evacuated. Moreover, in the etching chamber 10, a heater such as a lump heater (not shown) may be arranged. The heater is configured so as to heat the substrate W to the degree that ammonium fluorosilicate to be described later is volatilized (about 100° C.). The heater is not limited to the lump heater, and may be a resistance heating heater, for example. Moreover, the heater may be arranged outside the etching chamber 10.

The wafer boat 12 is configured so as to hold 50 substrates W, for example. The wafer boat 12 holds the substrates W in the thickness direction of the substrate W so that the substrates W face each other, for example, and is arranged in the etching chamber 10 so that the thickness direction is substantially in parallel with the height direction of the etching chamber 10. Accordingly, it is possible to perform the etching process on the substrates W at the same time.

The reactive gas supplying mechanism 11 supplies the first reactive gas for etching a natural oxide film on the substrate W to the etching chamber 10. In this embodiment, the first reactive gas is an ammonium fluoride gas. Specifically, the ammonium fluoride gas reacts with the natural oxide film on the surface of the substrate W, and thus, it is converted into volatile ammonium fluorosilicate and is removed. The ammonium fluoride gas is generated by the reaction of a nitrogen fluoride gas with a hydrogen radical in the etching chamber 10.

The reactive gas supplying mechanism 11 includes a nitrogen fluoride gas supplying unit (third supplying unit) 13 that is capable of supplying a nitrogen fluoride gas and a hydrogen radical supplying unit (fourth supplying unit) 14 that is capable of supplying a hydrogen radical, and is configured so as to introduce the nitrogen fluoride gas and the hydrogen radical into the etching chamber 10.

The hydrogen radical supplying unit 14 excites ammonia (NH₃) and generates a hydrogen radical. The hydrogen radical supplying unit 14 includes a gas supplying source 141 to which an ammonia gas and a nitrogen (N₂) gas being a carrier gas thereof are supplied, a gas supplying path 142, a microwave exciting unit 143, a hydrogen radical supplying path 144, and a hydrogen radical introducing head 145. Although not shown, a mass flow controller for controlling the flow rate of gas may be arranged in the gas supplying path 142.

The microwave exciting unit 143 applies a microwave to an ammonia gas introduced via the gas supplying path 142 to excite the ammonia gas, and generates a hydrogen radical (H*) by making a hydrogen gas in a plasma state.

The hydrogen radical supplying path 144 is joined to the etching chamber 10. Specifically, with reference to FIG. 2, the hydrogen radical supplying path 144 is connected to the hydrogen radical introducing head 145 arranged on the inner wall surface of the etching chamber 10 along the height direction. In the hydrogen radical introducing head 145, a plurality of holes are formed inward of the etching chamber 10 to have a uniform distribution, and the hydrogen radical introducing head 145 is formed so that hydrogen radicals are introduced from the holes into the etching chamber 10. It should be noted that as shown in FIG. 2, the microwave exciting unit 143 and the hydrogen radical supplying path 144 may be diverged into two paths from the gas supplying path 142, and the respective paths may be connected to the hydrogen radical introducing head 145.

The nitrogen fluoride gas supplying unit 13 includes a nitrogen fluoride gas supplying source 131, a nitrogen fluoride gas supplying path 132, and a shower nozzle 133. As the nitrogen fluoride gas, a nitrogen trifluoride gas is used, for example. Moreover, in the nitrogen fluoride gas supplying path 132, a mass flow controller for controlling the flow rate of gas (not shown) may be arranged.

With reference to FIG. 2, in this embodiment, the tip portion of the nitrogen fluoride gas supplying path 132 is inserted from the ceiling to the bottom of the etching chamber 10. The tip portion is arranged in the diameter direction of the etching chamber 10 so as to face the hydrogen radical introducing head 145, for example. On the lateral surface of the tip portion, the shower nozzle 133 including a plurality of holes is formed. In the shower nozzle 133, a plurality of holes are formed to have a substantially uniform distribution in the height direction of the etching chamber 10, and the shower nozzle 133 is configured so that a nitrogen trifluoride gas is introduced from the holes into the etching chamber 10.

The nitrogen trifluoride gas and the hydrogen radical are mixed and reacted with each other in the etching chamber 10, and thus, an ammonium fluoride (NH_{X}F_{Y}) gas is generated. In this embodiment, the plurality of holes of the hydrogen radical introducing head 145 and the shower nozzle 133 are distributed uniformly in the height direction of the etching chamber 10, and thus, it is possible to cause the ammonium fluoride gas to act on the plurality of substrates W evenly.

### (Deposition Chamber)

The deposition chamber 20 includes a reactive gas supplying mechanism (second supplying mechanism) 21 that supplies a second reactive gas, a raw material gas supplying mechanism (third supplying mechanism) 22 that supplies a raw material gas for forming a film, a wafer boat (substrate holder) 23, and a heater (heating mechanism) H. The deposition chamber 20 holds the substrate W by the wafer boat 23 and cleans the surface of the substrate W with the second reactive gas, before causing a film including at least one of silicon and germanium to grow on the surface of the substrate W by a vapor-phase epitaxial growth method.

The deposition chamber 20 is configured as a vertical epitaxial vapor phase growing apparatus, for example. Specifically, the deposition chamber 20 has a cylindrical shape as a whole, and the axial direction (hereinafter, referred to as height direction of the deposition chamber 20) is arranged in parallel with the vertical direction. Moreover, the deposition chamber 20 is connected to the transporting chamber 32 via a gate valve G2. Moreover, the deposition chamber 20 is connected to an evacuation pump P2 formed of a dry pump or a turbo molecular pump, and is configured so that the inside thereof can be vacuum-evacuated.

In this embodiment, the heater H is configured as a resistance heating furnace for heating the outer wall of the deposition chamber 20. Specifically, the heater H employs a hot wall system. The heater H heats the substrate W by heating the deposition chamber 20 to not more than 800° C., e.g., 400° C. to 700° C. At such a temperature, it is possible to cause a film including silicon or the like to grow on the surface of the substrate W and to prevent the diffusion profile of impurity ions doped in the substrate W from collapsing.

The wafer boat 23 is configured so as to hold 25 substrates W, for example. The wafer boat 23 holds the plurality of substrates W so that the substrates W face each other in the thickness direction of the substrates W. Accordingly, it is possible to perform a process on the plurality of substrates W at the same time.

The reactive gas supplying mechanism 21 supplies the second reactive gas for cleaning the surface of the substrate W. In this embodiment, the second reactive gas is a hydrogen radical. Specifically, the hydrogen radical reduces a reactant or the like with C, F, and the like formed on the surface of the substrate W, or chemically combines, with a hydrogen, a reactant or the like with C, F, and the like formed on the surface of the substrate W to remove it. Thus, it is possible to clean the surface of the substrate W.

In this embodiment, the reactive gas supplying mechanism 21 includes a hydrogen radical supplying unit (first supplying unit) 24 that is capable of supplying a hydrogen radical. The hydrogen radical supplying unit 24 excites a hydrogen gas (H₂) to generate a hydrogen radical. The hydrogen radical supplying unit 24 includes a hydrogen gas supplying source 241, a hydrogen gas supplying path 242, a microwave exciting unit 243, and a hydrogen radical supplying path 244.

The microwave exciting unit 243 is configured similarly to the microwave exciting unit 143 of the hydrogen radical supplying unit 14, applies a microwave to the hydrogen gas introduced via the hydrogen gas supplying path 242 to excite the hydrogen gas, and generates a hydrogen radical by making the hydrogen gas in a plasma state.

The method of supplying a hydrogen radical from the hydrogen radical supplying path 244 to the deposition chamber 20 is not particularly limited as long as hydrogen radicals can be uniformly supplied to the plurality of substrates W arranged along the height direction. For example, the tip portion of the hydrogen radical supplying path 244 may be inserted into the deposition chamber 20, and hydrogen radicals may be supplied from a plurality of ejection holes arranged so as to be uniformly distributed in the height direction to the substrates W. Alternatively, it may be connected to a hydrogen radical introducing head or the like arranged on the inner wall surface of the deposition chamber 20 along the height direction.

The raw material gas supplying mechanism 22 supplies a raw material gas including at least one of silicon and germanium to the surface of the substrate W. In this embodiment, the raw material gas is a silane (SiH₄) gas. Accordingly, it is possible to cause a silicon single crystal film to grow on the surface of the substrate W.

The raw material gas supplying mechanism 22 includes a raw material gas source 221 and a raw material gas supplying path 222. Furthermore, in the raw material gas supplying path 222, a mass flow controller for controlling the flow rate of gas (not shown) may be arranged. At the tip portion of the raw material gas supplying path 222, a silane gas is supplied from the ejection hole to the substrate W. The ejection hole is not particularly limited as long as it has a configuration in which a silane gas can be supplied to the plurality of substrates W in view of the flow of gas in the deposition chamber 20, which is formed by the evacuation pump P2 or the like. For example, because the flow of gas flowing from downward to upward can be formed in the case where the evacuation pump P2 is arranged in the vicinity of the upper end of the deposition chamber 20, the ejection hole may be configured so as to be arranged at the lower end portion of the deposition chamber 20 and eject a gas upward.

### (Transporting Mechanism)

The transporting mechanism 30 includes a clean booth 31 and the transporting chamber 32. The clean booth 31 includes a transferring robot 34 and a wafer cassette 35 that is capable of accommodating the substrate W, and has a function as a loading chamber and an extraction chamber of the substrate W in the deposition chamber 1. The transporting chamber 32 includes a transferring robot 36, and transports the substrate W between the clean booth 31, the etching chamber 10, and the deposition chamber 20. The transporting mechanism 30 is configured so as to be capable of transporting the plurality of substrates W between the clean booth 31, the etching chamber 10, and the deposition chamber 20 under vacuum.

The clean booth 31 is connected to the transporting chamber 32 via a gate valve G3. In the clean booth 31, the substrate W is transferred from the wafer cassette 35 to the transferring robot 36 arranged in the transporting chamber 32 by the transferring robot 34.

The transporting chamber 32 is connected to the etching chamber 10 via the gate valve G1, and to the deposition chamber 20 via the gate valve G2. To the transporting chamber 32, an evacuation pump P3 formed of a dry pump or a turbo molecular pump is connected. The transporting chamber 32 is configured so that the inside thereof can be vacuum-evacuated. Accordingly, the substrate W can be transported from the etching chamber 10 to the deposition chamber 20 under vacuum.

The transporting chamber 32 is configured so that the transferring robot 36 transports the substrate W from the clean booth 31 to the etching chamber 10 and from the etching chamber 10 to the deposition chamber 20. For example, the transferring robot 36 may include a wafer cassette (not shown) that is capable of accommodating the substrate W. Accordingly, the transferring robot 36 can easily perform delivery of the substrate W between the transferring robot 36 and the wafer boat 12 of the etching chamber 10 or the wafer boat 23 of the deposition chamber 20.

With the configuration, because the deposition chamber 1 can perform vacuum transportation between the etching chamber 10 and the deposition chamber 20, it is possible to prevent a natural oxide film from reattaching and to clean the substrate W in the deposition chamber 20 more efficiently. Moreover, because the deposition chamber 1 includes the etching chamber 10 and the deposition chamber 20, it is possible to perform a series of processes in a short time period without performing the processes in the separated apparatuses.

Furthermore, because the deposition chamber 1 employs a batch process system, it is possible to perform a process on a lot of substrates W at the same time and to improve the productivity.

Next, a deposition method according to this embodiment will be described.

### [Deposition Method]

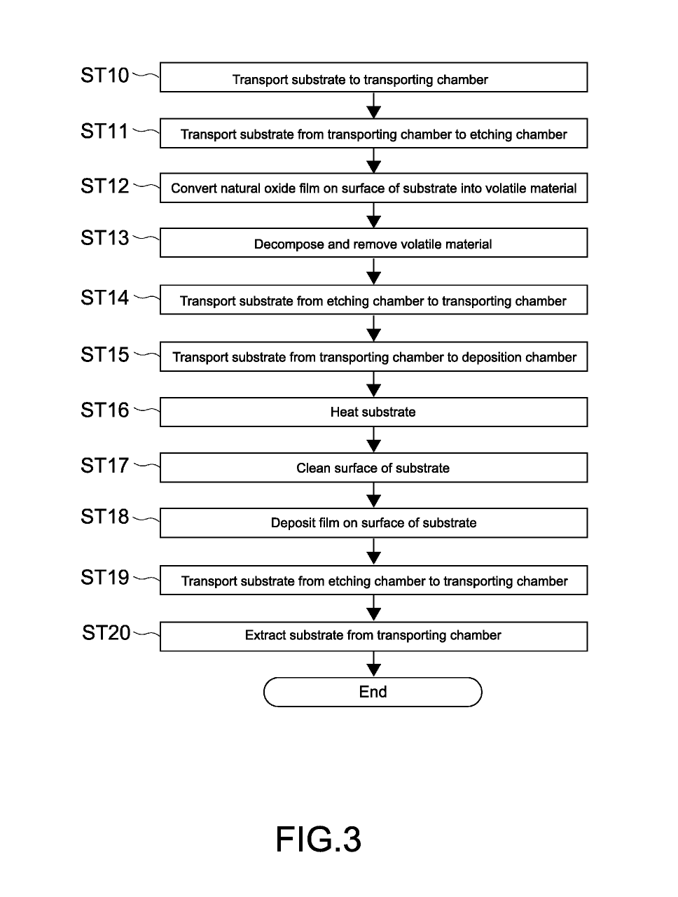

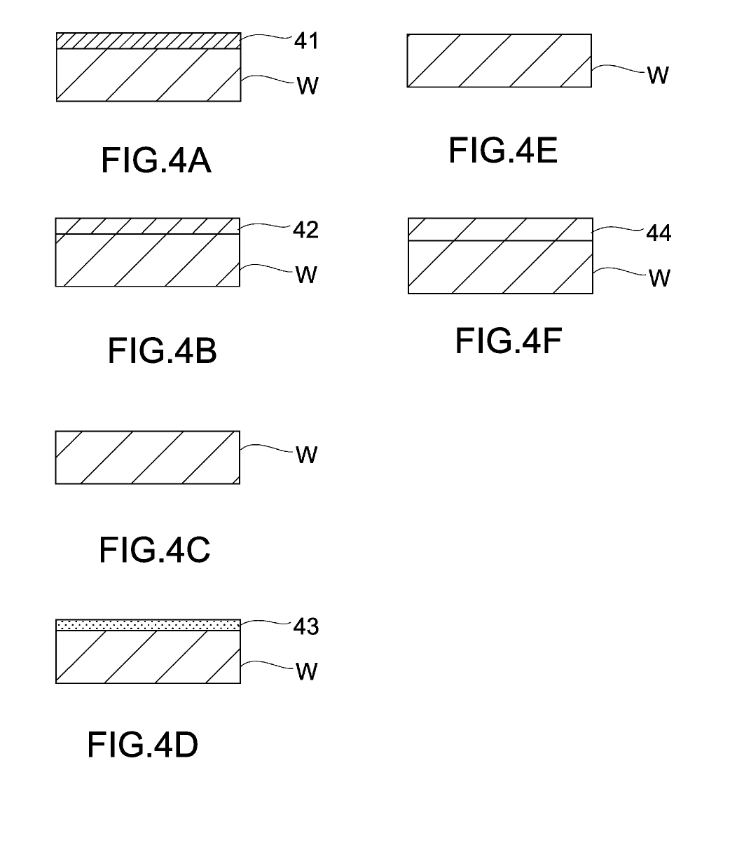

FIG. 3 is a flowchart for explaining a deposition method according to this embodiment. FIGS. 4A, B, C, D, E, and F are each a schematic view showing a form of the substrate W in each process of the deposition method according to this embodiment. The deposition method according to this embodiment includes a process of transporting a silicon substrate to an etching chamber, a process of etching a natural oxide film on a surface of the silicon substrate, a process of transporting the silicon substrate from the etching chamber to a deposition chamber under vacuum, a process of cleaning the surface of the silicon substrate, and a process of causing a film to grow on the surface of the silicon substrate. Hereinafter, each process will be described.

### (Transporting Process to Etching Chamber)

First, the substrate W is transported to the etching chamber 10. Specifically, it is performed in the following way. That is, the wafer cassette 35 on which the substrate W is mounted is introduced into the clean booth 31. Next, the gate valve G3 is opened to drive the transferring robot 34, the substrate W is transferred from the wafer cassette 35 to the transferring robot 36, and the substrate W is transported to the transporting chamber 32 (step ST10). Then, the gate valve G3 is closed to drive the evacuation pump P3, and the transporting chamber 32 is evacuated. Furthermore, the gate valve G1 is opened, and the substrate W is transported from the transporting chamber 32 to the etching chamber 10 by the transferring robot 36 (step ST11). It should be noted that the etching chamber 10 is evacuated by the evacuation pump P1 in advance.

FIG. 4A is a diagram showing a form of the substrate W in the process of transporting the substrate W to the etching chamber. With reference to FIG. 4A, a natural oxide film 41 is formed on the surface of the substrate W. The thickness of the natural oxide film 41 is about 2 to 3 nm, for example. It should be noted that in FIGS. 4A to F, the thickness of a film such as the natural oxide film 41 formed on the surface of the substrate W is described more exaggeratingly than the actual one for explanation. Typically, an organic material, metal, and the like attached to the surface of the substrate W are removed in advance by wet cleaning or the like before the substrate W is introduced into the clean booth 31. However, because the surface of the silicon substrate is very active, the natural oxide film 41 formed of SiO₂ is easily formed if the silicon substrate is exposed in the atmosphere in the clean booth 31 or the like. Moreover, not only the natural oxide film 41 but also a compound or the like including C or F is also attached to the surface of the substrate W and is reacted easily.

### (Etching Process)

The etching process according to this embodiment includes a process of converting a natural oxide film formed on the surface of the substrate W into a volatile material and a process of removing the volatile material formed on the substrate W by decomposing the volatile material.

FIG. 4B is a diagram showing a form of the substrate W after the natural oxide film 41 is converted into a volatile material (ammonium fluorosilicate) 42. As shown in FIG. 4B, a reactive gas is introduced into the etching chamber 10, and the natural oxide film formed on the surface of the substrate W is converted into a volatile material (step ST12). Specifically, a nitrogen trifluoride gas is introduced by the nitrogen fluoride gas supplying unit 13, and a hydrogen radical is introduced by the hydrogen radical supplying unit 14. An ammonia gas is supplied from the gas supplying source 141 in the hydrogen radical supplying unit 14, and a microwave of about 2.45 GHz, for example, is applied to the ammonia gas in the microwave exciting unit 143. Accordingly, a hydrogen radical (H*) is generated by exciting the ammonia gas as shown in the following formula.

NH₃→NH₂+H* (1)

In the etching chamber 10, the introduced nitrogen trifluoride gas and hydrogen radical are reacted with each other, and an ammonium fluoride (NH_{X}F_{Y}) gas is generated as shown in the following formula.

H*+NF₃→NH_{X}F_{Y}(NH₄F, NH₄FH, NH₄FHF or the like) (2)

The generated ammonium fluoride gas acts on the natural oxide film formed on the surface of the substrate W, and volatile ammonium fluorosilicate ((NH₄)₂SiF₆) is generated as shown in the following formula.

SiO₂+NH_{X}F_{Y}(NH₄)₂SiF₆+H₂O (3)

As a processing condition of the above-mentioned process, the processing pressure in the etching chamber 10 is about 300 Pa (the flow rate of ammonia gas for generating a hydrogen plasma is 10 to 1500 sccm, and the flow rate of nitrogen trifluoride gas is 500 to 5000 sccm), for example. Moreover, the processing temperature is not more than 100° C., and the process can be performed at room temperature (about 25° C.). Under the above-mentioned conditions, after the natural oxide film 41 is reacted for a predetermined time period until the natural oxide film 41 is fully converted into a volatile material, the supply of the reactive gas and application of the microwave are stopped, and the etching chamber 10 is evacuated by the evacuation pump P1.

Next, a lump heater or the like is driven to heat the substrate W and remove the ammonium fluorosilicate 42 generated on the substrate W by decomposing the ammonium fluorosilicate 42 (step ST13). In this process, the silicon substrate is heated to not less than 100° C., favorably 200 to 250° C. Accordingly, it is possible to remove the ammonium fluorosilicate 42 being a volatile material by decomposing and volatilizing the ammonium fluorosilicate 42. After the ammonium fluorosilicate 42 is maintained at the above-mentioned temperature for a predetermined time period until the ammonium fluorosilicate 42 is fully volatilized, the heater is stopped.

FIG. 4C is a diagram showing a form of the substrate W after the etching process. As shown in FIG. 4C, after the end of this process, the surface of the substrate W is cleaned and the natural oxide film 41 is removed.

### (Vacuum Transportation Process)

In the vacuum transportation process, the substrate W is transported from the etching chamber 10 to the deposition chamber 20 under vacuum. Specifically, first, the gate valve G1 is opened, and the substrate W is transported to the transporting chamber 32 by the transferring robot 36 (step ST14). Then, the gate valve G1 is closed, the substrate W is transported by the transferring robot 36, the gate valve G2 is opened, and the substrate W is transported to the deposition chamber 20 (step ST15). At this time, the transporting chamber 32 is evacuated by the evacuation pump P3. Accordingly, because the substrate W is transported in the transporting chamber 32 under vacuum, the reformation of the natural oxide film on the surface of the substrate W is prevented.

FIG. 4D is a diagram showing a form of the substrate W after the vacuum transportation process. On the surface of the substrate W, the natural oxide film is almost not formed, but a reactant 43 is formed. The reactant 43 is derived from, for example, a single C atom, a compound thereof, a compound of F or the like, or a compound including O or the like.

For example, the etching chamber 10, the transporting chamber 32, and the deposition chamber 20, which are normally maintained in a vacuum atmosphere, are exposed in the atmosphere periodically because of maintenance or the like, and thus, a compound or the like of C is attached to the inside of these chambers. Moreover, because a lubricating agent or the like of the respective members in the deposition chamber 20 contains a compound including F or the like, the compound may float in the etching chamber 10, the transporting chamber 32, and the deposition chamber 20. Here, the surface of the substrate W right after the removal of the natural oxide film 41 is in a very active state. Therefore, a compound including F or the like, a single C atom or the like, or a compound thereof reacts with the surface of the substrate W easily, and thus, the reactant 43 can be generated.

In the case where a silicon single crystal film or the like is caused to grow on the surface of the silicon substrate W to which the reactant 43 is attached, the crystal arrangement of Si is disturbed, which becomes a cause of crystal defect. Moreover, the growth of the film may be inhibited. In view of the above, in order to remove them, the surface of the substrate W is cleaned.

### (Cleaning Process)

In the process of cleaning the surface of the substrate W, first, the heater H of the deposition chamber 20 is driven to heat the silicon substrate W to not more than 800° C., e.g., 400 to 700° C. (step ST16). Then, the surface of the substrate W is cleaned by using a gas including a hydrogen radical (step ST17). Specifically, a hydrogen radical is introduced from the hydrogen radical supplying unit 24 into the deposition chamber 20, and the reactant on the surface of the substrate W is reduced. Accordingly, these materials are removed by being volatilized, for example, and thus, the surface of the substrate W is cleaned.

In the hydrogen radical supplying unit 24, a hydrogen gas (H₂) is excited to generate a hydrogen radical. Specifically, a hydrogen gas is supplied from the hydrogen gas supplying source 241, and a microwave is applied to the hydrogen gas in the microwave exciting unit 243. In the microwave exciting unit 243, for example, a microwave of about 2.45 GHz is applied. Accordingly, the hydrogen gas is excited as shown in the following formula to generate a hydrogen radical (H*).

H₂→2H* (4)

The hydrogen radical is more active than a normal hydrogen (hydrogen molecule, hydrogen ion) and has a reduction power greater than the normal hydrogen. Accordingly, it is possible to reduce a material at a temperature not more than 800° C. and to remove the material.

As a processing condition of the above-mentioned process, the processing pressure in the deposition chamber 20 is about 100 to 500 Pa (the flow rate of hydrogen plasma is 5 to 1000 sccm), for example. After the cleaning for about 1 to 60 minutes, the irradiation of microwave and the supply of hydrogen plasma are stopped, and the deposition chamber 20 is evacuated by the evacuation pump P2.

FIG. 4E is a diagram showing a form of the substrate W after the cleaning process. The natural oxide film 41 and the reactant 43 are not adsorbed on the surface of the substrate W, and thus, the surface of the substrate W is in a clean state.

### (Deposition Process)

Next, on the cleaned surface of the substrate W, a film including at least one of silicon and germanium is caused to grow (step ST18). In this embodiment, in order to cause a silicon single crystal film to grow, a silane gas being a raw material gas is introduced by the raw material gas supplying mechanism 22. The silane gas being a raw material gas is thermally decomposed, crystals of Si are arranged on the surface of the substrate W, and the silicon single crystal film is caused to grow. It should be noted that hereinafter, this process to cause a film to grow on the substrate W is referred to as “Deposition Process.”

As a processing condition of the above-mentioned process, the processing pressure in the deposition chamber 20 is about 0.1 to 266 Pa (the flow rate of silane gas is 10 to 500 sccm), for example. In such a condition, it is possible to cause a silicon single crystal film to grow so as to have a desired film thickness. It should be noted that also in this embodiment, the temperature in the deposition chamber 20 is controlled to be approximately same temperature as that in the cleaning process (e.g., 400 to 700° C.).

After that, the heater H is stopped, the supply of raw material gas is stopped, and the deposition chamber 20 is evacuated by the evacuation pump P2. Next, the substrate W is transported to the transporting chamber 32 (step ST19) by the transferring robot 36, and the substrate W is transferred from the transporting chamber 32 to the wafer cassette 35 of the clean booth 31. Thus, the substrate W is extracted (step ST20).

FIG. 4F is a diagram showing a form of the substrate W after the deposition process. On the surface of the substrate W, the silicon single crystal film 44 is formed. In this embodiment, because a film is cause to grow on the surface of the substrate W in a clean state shown in FIG. 4E, the single crystal film 44 having excellent crystallinity, which is aligned in the same way as the surface of the substrate W, is formed

In this way, in the deposition method according to this embodiment, it is possible to remove, by etching, the natural oxide film formed on the surface of the substrate W and to clean the surface. Therefore, it is possible to clean the material attached in the deposition chamber 20 and the material that cannot be removed in the etching process, and to clean the surface of the substrate W more reliably. Accordingly, it is possible to cause a desired single crystal film to grow on the surface of the substrate W.

Moreover, in the above-mentioned method, the substrate W is cleaned in the deposition chamber 20 right before the deposition process. Accordingly, it is possible to remove, for example, the material attached during the vacuum transportation or in the deposition chamber 20, and to cause a film to grow on the cleaner surface of the substrate W.

Furthermore, in this embodiment, a hydrogen radical having a great reduction power is used to clean the surface of the substrate W. Accordingly, it is possible to perform a reduction process at a relatively low temperature such as 400 to 700° C. Therefore, it is possible to perform the cleaning and the subsequent growing of film without collapsing the diffusion profile of impurity ions doped on the substrate W.

### Second Embodiment

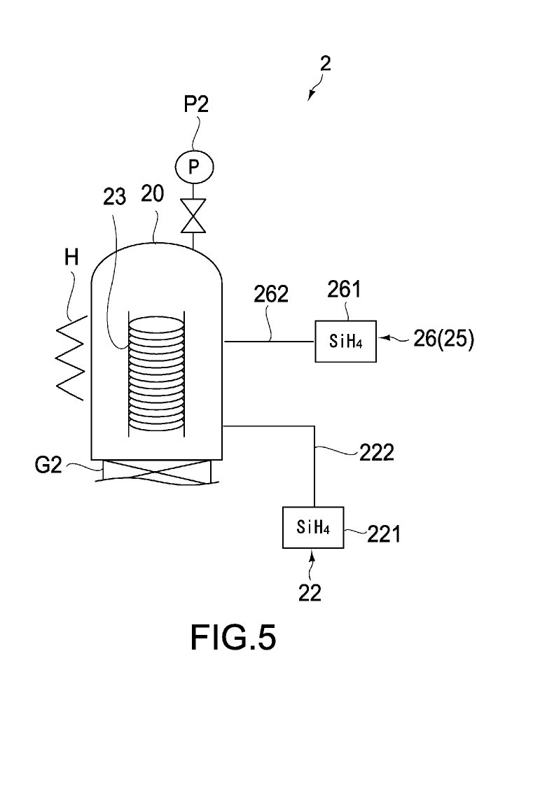

FIG. 5 is a schematic configuration diagram showing a main portion of a deposition apparatus according to a second embodiment of the present invention. It should be noted that the same components as those according to the first embodiment will be denoted by the same reference symbols and a description thereof will be omitted.

The deposition apparatus 2 according to the second embodiment is different from the deposition apparatus 1 according to the first embodiment in that a silane (SiH₄) gas being a deposition gas is used as the second reactive gas for cleaning the surface of the substrate W. Accordingly, a reactive gas supplying mechanism (second supplying mechanism) 25 of the deposition chamber 20 includes a sinlae gas supplying unit (second supplying unit) 26 that is capable of supplying a silane-based gas. Specifically, in this embodiment, the silane gas reduces the reactant formed on the surface of the substrate W, for example, whereby cleaning the surface of the substrate W.

The silane gas supplying unit 26 includes a silane gas supplying source 261 and a silane gas supplying path 262. Moreover, in the silane gas supplying path 262, a mass flow controller (not shown) is arranged. Accordingly, it is possible to control the flow rate of silane gas supplied in the deposition chamber 20.

The method of supplying a silane gas from the silane gas supplying path 262 to the deposition chamber 20 is not particularly limited as long as the silane gas can be uniformly supplied to the plurality of substrates W arranged along the height direction. For example, the tip portion may be inserted into the deposition chamber 20, and the silane gas may be supplied from a plurality of ejection holes arranged so as to be uniformly distributed in the height direction to the substrates W similarly to the hydrogen radical supplying path 244 according to the first embodiment. Alternatively, it may be connected to a silane gas introducing head or the like arranged on the inner wall surface of the deposition chamber 20 along the height direction.

The raw material gas supplying mechanism 22 uses a silane gas as a raw material gas and is configured similarly to that in the first embodiment. Specifically, the raw material gas supplying mechanism 22 includes the raw material gas source 221 and the raw material gas supplying path 222. Furthermore, in the raw material gas supplying path 222, a mass flow controller for controlling the flow rate of gas (not shown) is arranged. The tip portion of the raw material gas supplying path 222 is configured so that a silane gas is uniformly supplied from the ejection hole to the plurality of substrates W.

The cleaning process in the deposition method according to this embodiment is performed with the substrate W being heated to 800° C. or less, e.g., 400 to 700° C. similarly to the first embodiment. Then, a gas including a silane gas is used to clean the surface of the substrate W. Specifically, a silane gas is introduced from the silane gas supplying unit 26 into the deposition chamber 20, and the reactant formed on the surface of the substrate W is reduced, for example. Accordingly, these materials are removed by being volatilized, and the surface of the substrate W is cleaned.

Here, the flow rate of silane gas used in the cleaning process (second flow rate) is, for example, 20 to 70 cc/min. With such a flow rate of silane gas, the reduction action on the material is sufficiently exerted.

After the cleaning for about 1 to 60 minutes, the supply of silane gas from the silane gas supplying unit 26 is stopped. Here, in this embodiment, because the deposition process is performed in the atmosphere of silane gas subsequently, there is no need to evacuate the deposition chamber 20 by the evacuation pump P2 and it is possible to develop the process efficiently.

Next, in the state where the temperature in the deposition chamber 20 is controlled to be 400 to 700° C., a silane gas is introduced by the raw material gas supplying mechanism 22, and a silicon single crystal film is caused to grow on the surface of the substrate W.

The flow rate of silane gas used in the deposition process (first flow rate) is, for example, about 500 cc/min. Specifically, since the flow rate of silane gas used in the cleaning process is, for example, 20 to 70 cc/min, it is controlled to be lower than that in the deposition process. As described above, by controlling the flow rate of silane gas, it is possible to clean the surface without causing a film including silicon to grow on the surface of the substrate W in the cleaning process.

As described above, in this embodiment, a deposition gas is used to clean the surface of the substrate W. Accordingly, contamination does not occur due to the gas used to clean the growing film. Moreover, it is possible to perform the cleaning process and the process of causing a film to grow in a short time without evacuating the deposition chamber 20 by the evacuation pump P2 because the cleaning process and the deposition process can be performed continuously without changing the atmosphere. Furthermore, it is possible to cause a single crystal silicon film having high quality to grow on the surface of the silicon substrate W without managing the time condition of the cleaning process strictly.

### Third Embodiment

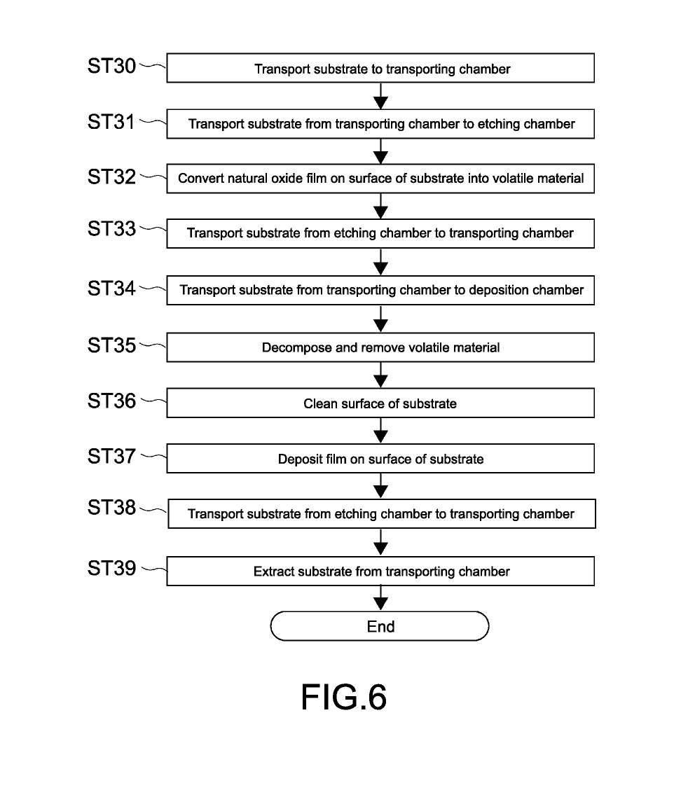

FIG. 6 is a flowchart of a deposition method according to a third embodiment of the present invention. It should be noted that the same components as those according to the first embodiment will be denoted by the same reference symbols and a description thereof will be omitted.

The deposition method according to the third embodiment is different from the deposition method according to the first embodiment in that the process of decomposing volatile ammonium fluorosilicate generated on the substrate W in the deposition chamber 20 is performed.

The transportation process to the etching chamber is performed in the same way as that in the first embodiment. Specifically, the substrate W is transferred from the wafer cassette 35 arranged in the clean booth 31 to the transferring robot 36, and the substrate W is transported to the transporting chamber 32 (step ST30). Next, the substrate W is transported from the transporting chamber 32 to the etching chamber 10 by the transferring robot 36 (step ST31).

Next, a reactive gas is introduced into the etching chamber 10, and the natural oxide film formed on the surface of the substrate W is converted into ammonium fluorosilicate being a volatile material similarly to the first embodiment (step ST32).

Next, in the state where the volatile material is attached to the surface of the substrate W, the substrate W is transported to the transporting chamber 32 (step ST33). Furthermore, the gate valve G2 is opened, and the substrate W is transported to the deposition chamber 20 (step ST34).

Next, the heater H of the deposition chamber 20 is driven to heat the substrate W to 400 to 700° C., and the volatile material formed on the substrate W is removed by being decomposed and volatilized (step ST35). Accordingly, the natural oxide film formed on the substrate W is removed.

Because the subsequent cleaning process and deposition process are performed in the same way as that of the first embodiment, a description thereof will be omitted. Specifically, the steps ST36 to ST39 in FIG. 6 correspond to the steps ST17 to ST20 in FIG. 4, respectively.

In this embodiment, the volatile material generated by conversion of the natural oxide film in the etching process is decomposed not in the etching chamber 10 but in the deposition chamber 20. The ammonium fluorosilicate being a volatile material is decomposed and volatilized at about 250° C. On the other hand, the deposition chamber 20 needs to be heated to 400 to 700° C. by the heater H in order to perform the cleaning process and the deposition process. Therefore, it is possible to decompose ammonium fluorosilicate using heating by the heater H, and to simplify the process. Accordingly, the entire process time can be shortened, and the productivity can be improved.

Moreover, the etching chamber 10 can have a configuration that has no heater, and thus, the apparatus configuration can be simplified.

Although embodiments of the present invention have been described, the present invention is not limited thereto and various modifications can be made based on the technical ideas of the present invention.

For example, as a modified example of the second embodiment, in the case where a film including germanium (Ge) is caused to grow on the surface of the substrate W, a germane gas (GeH₄) being a deposition gas may be used to clean the surface of the substrate W. The germane gas can reduce the material of C, F, and the like formed on the surface of the substrate W to clean the surface of the substrate W, similarly to the silane gas.

It should be noted that the deposition apparatus 2 according to the modified example can be configured so that the second supplying unit 26 that supplies a cleaning gas and the raw material gas supplying mechanism 22 that supplies a raw material gas include a germane gas supplying source instead of the silane gas supplying source.

Moreover, as a processing condition of the cleaning process, the processing temperature can be 400 to 700° C. Moreover, the processing time of the cleaning process is not limited as long as the natural oxide film on the surface of the substrate W can be fully removed, and it is possible to cause a film including germanium to appropriately grow on the surface of the silicon substrate without managing the time condition of the cleaning process strictly also in this modified example.

Moreover, the film caused to grow on the surface of the substrate W is not limited to the silicon film or germanium film, and may be a synthesized film of silicon and germanium. In this case, as a deposition gas, a hydrogen gas, silane gas, and germane gas can be employed. Moreover, as the cleaning gas, the above-mentioned gas including a hydrogen radical, silnae gas, germane gas, or the like can be appropriately employed. In particular, in the case where a silane gas or a germane gas is used as the cleaning gas, it is possible to prevent the contamination from occurring, to shorten the processing time period and to improve the productivity, as a modified example of the second embodiment in which a deposition gas is used as the cleaning gas.

Moreover, in the above-mentioned embodiments, an ammonia gas is used for generating a hydrogen radical in the etching process, but a nitrogen gas or hydrogen gas may be used, for example. Moreover, the excitation of the ammonia gas or the like is also not limited to the method of applying a microwave. Furthermore, the etching process is not limited to the method of using the nitrogen trifluoride and hydrogen radical, and can employ another method appropriately as long as the natural oxide film formed on the silicon substrate W can be removed.

In the first embodiment, not only the hydrogen gas but also a nitrogen gas or an ammonia gas may be used for generating a hydrogen radical in the cleaning process. Moreover, in the second embodiment, the gas used in the cleaning process is not limited to a silane gas and germane gas, and another silane-based gas such as disilane (Si₂H₆) gas or another germane-based gas such as a digermane (Ge₂H₆) gas can be used.

In the second embodiment, although the silane gas used as a cleaning gas and the silane gas used as a raw material gas are described to be supplied from the second and third mechanisms 22 and 25, respectively, these supplying mechanisms may be configured integrally and the silane gas may be supplied from the same plumbing. Accordingly, it is possible to simplify the apparatus configuration.

In the first embodiment, in the deposition apparatus 1, a process for preventing a hydrogen radical from being deactivated (specifically, coating with a coated layer formed of aluminum hydrate such as an alumite film) may be applied to the inner wall surfaces of the etching chamber 10 and the deposition chamber 20. Accordingly, it is possible to suppress the mutual reaction between the inner wall surfaces of the etching chamber 10 and the deposition chamber 20 and the hydrogen radical, to use the hydrogen radical for the process of the substrate reliably, and to improve the uniformity in the surface of the substrate W. Moreover, also in the second embodiment, it is possible to apply the similar process to the inner wall of the etching chamber 10 into which the hydrogen radical is introduced.

Moreover, the number of etching chambers and deposition chambers in the deposition apparatus is not particularly limited, and can be appropriately set depending on the setting place, a desired processing capacity, or the like. For example, the deposition apparatus can include one etching chamber and two deposition chambers, and can employ a configuration to include two etching chambers and two deposition chambers. Moreover, it is possible to employ a configuration in which three or more etching chambers and three or more deposition chambers are arranged. Accordingly, it is possible to improve the productivity.

Moreover, although any of the etching chamber and the deposition chamber in the deposition apparatus is described to employ a batch process system in the above-mentioned embodiments, it is not limited thereto. For example, a so-called sheet-type system in which one substrate is arranged in the etching chamber and the deposition chamber may be employed.

Moreover, the heater H in the deposition chamber is described to employ a hot wall system by a resistance heating furnace, but it is not limited thereto. For example, a heater using a so-called cold wall system in which a lump heater is arranged in the deposition chamber to heat the substrate may be employed.

### DESCRIPTION OF REFERENCE NUMERALS

1, 2 deposition apparatus
10 etching chamber
11 reactive gas supplying mechanism (first supplying mechanism)
12, 23 wafer boat (substrate holder)
13 nitrogen fluoride gas supplying unit (third supplying unit)
14 hydrogen radical supplying unit (fourth supplying unit)
20 deposition chamber
21, 25 reactive gas supplying mechanism (second supplying mechanism)
24 raw material gas supplying mechanism (third supplying mechanism)
22 hydrogen radical supplying unit (first supplying unit)
26 silane gas supplying unit (second supplying unit)
30 transporting mechanism
H heater (heating mechanism)

1. A deposition method, comprising:
etching a natural oxide film in an etching chamber, the natural oxide film being formed on a surface of a silicon substrate;
transporting the silicon substrate from the etching chamber to a deposition chamber under vacuum;
cleaning the surface of the silicon substrate in the deposition chamber; and
causing a film to grow on the cleaned surface of the silicon substrate in the deposition chamber, the film including at least one of silicon and germanium.

2. The deposition method according to claim 1, wherein
in the process of cleaning the surface of the silicon substrate, a gas including a hydrogen radical is used to clean the surface of the silicon substrate.

3. The deposition method according to claim 1, wherein
in the process of cleaning the surface of the silicon substrate, a deposition gas is used to clean the surface of the silicon substrate.

4. The deposition method according to claim 3, wherein
in the process of causing a film to grow, a silane-based gas is used to cause a film including silicon to grow on the surface of the silicon substrate, and
in the process of cleaning the surface of the silicon substrate, the silane-based gas is used to clean the surface of the silicon substrate.

5. The deposition method according to claim 4, wherein
in the process of causing a film to grow, the silane-based gas having a first flow rate is used to cause a film including silicon on the surface of the silicon substrate, and
in the process of cleaning the surface of the silicon substrate, the silane-based gas having a second flow rate is used to clean the surface of the silicon substrate, the second flow rate being less than the first flow rate.

6. The deposition method according to claim 3, wherein
in the process of causing a film to grow, a germane-based gas is used to cause a film including germanium to grow on the surface of the silicon substrate, and
in the process of cleaning the surface of the silicon substrate, the germane-based gas is used to clean the surface of the silicon substrate.

7. The deposition method according to claim 1, wherein
in the processes of cleaning the surface of the silicon substrate and causing a film to grow, the silicon substrate is heated to not more than 800° C.

8. The deposition method according to claim 1, wherein
in the process of etching a natural oxide film, the natural oxide film is converted into volatile ammonium fluorosilicate by causing the natural oxide film to react with an ammonium fluoride gas.

9. The deposition method according to claim 1, wherein
in the processes of cleaning the surface of the silicon substrate, surfaces of a plurality of silicon substrates are cleaned at the same time,
in the process of causing a film to grow, films are caused to grow on the plurality of silicon substrates at the same time.

10. A deposition apparatus, comprising:
an etching chamber including a first supplying mechanism that supplies a first reaction gas for etching a natural oxide film formed on a surface of a silicon substrate;
a deposition chamber including
a second supplying mechanism that supplies a second reaction gas for cleaning the surface of the silicon substrate,
a third supplying mechanism that supplies a raw material gas including at least one of silicon and germanium to the surface of the silicon substrate, and
a heating mechanism that heats the silicon substrate; and
a transporting mechanism that is capable of transporting the silicon substrate from the etching chamber to the deposition chamber under vacuum.

11. The deposition apparatus according to claim 10, wherein
the second supplying mechanism includes a first supplying unit that is capable of supplying a hydrogen radical.

12. The deposition apparatus according to claim 11, wherein
the second supplying mechanism includes a second supplying unit that is capable of supplying a silane-based gas.

13. The deposition apparatus according to claim 10, wherein the first supplying mechanism includes:
a third supplying unit that is capable of supplying a nitrogen fluoride gas, and
a fourth supplying unit that is capable of supplying a hydrogen radical.

14. The deposition apparatus according to claim 10, wherein the heating mechanism is configured to heat inside of the deposition chamber to not more than 800° C.

15. The deposition apparatus according to claim 10, wherein the etching chamber and the deposition chamber include respective substrate holders configured to be capable of holding a plurality of silicon substrates.

16-17. (canceled)
